(19) United States
(12) Patent Application Publication
(10) Pub. No.: US 2026/0026265 A1
(43) Pub. Date: Jan. 22, 2026

(54) MAGNETORESISTIVE RANDOM ACCESS MEMORY DEVICE AND METHOD FOR FABRICATING THE SAME

(71) Applicant: UNITED MICROELECTRONICS CORP., Hsin-Chu City (TW)

(72) Inventors: Chih-Wei Kuo, Tainan City (TW); Shun-Yu Huang, Kaohsiung City (TW); Yi-Wei Tseng, New Taipei City (TW); Chun-Lung Chen, Tainan City (TW); Chung-Yi Chiu, Tainan City (TW)

(73) Assignee: UNITED MICROELECTRONICS CORP., Hsin-Chu City (TW)

(21) Appl. No.: 18/798,855

(22) Filed: Aug. 9, 2024

(30) Foreign Application Priority Data
Jul. 19, 2024 (CN) 202410973755.3

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A magnetoresistive random access memory device includes a bottom electrode, a spin orbit torque layer, a magnetic tunneling junction and a top electrode. The spin orbit torque layer is disposed on the bottom electrode. The magnetic tunneling junction is disposed on the spin orbit torque layer. The top electrode is disposed on the magnetic tunneling junction.

### BACKGROUND OF THE INVENTION

### 1. Field of the Invention

The present disclosure relates to the field of semiconductor devices, and more particularly, to a magnetoresistive random access memory (MRAM) device and a method for fabricating the same.

### 2. Description of the Prior Art

With the thin and light trend of mobile devices and the requirement of the popularization of the internet of things (IoT) in the future, the industry's requirements for recording density and performance of memory devices are increased. MRAM devices have attracted high attention due to advantages of fast read and write speed, non-volatility, and easy integration with semiconductor manufacturing processes, etc.

However, the MRAM devices on the market have not yet met expectations in all aspects. For example, spin torque transfer (STT) is one of the techniques adopted by current MRAM devices to switch the magnetic moment. When using STT to switch the magnetic moment, the two ferromagnetic layers of the magnetic tunneling junction (MTJ) receive the transfer torque provided by the current at the same time. Therefore, the difference of the coercivity between the upper and lower ferromagnetic layers is very small, and there is a certain probability that the magnetic moment in the free layer and the magnetic moment in the reference layer (also called as a pinned layer) are switched at the same time during writing, resulting in write errors. To reduce write errors, the waiting time of write is required to be maintained at a certain minimum value, so that the write speed of the STT type MRAM device cannot be enhanced. Therefore, how to improve the performance of the MRAM devices is still one of the topics in the industry.

### SUMMARY OF THE INVENTION

According to one aspect of the present disclosure, a MRAM device includes a bottom electrode, a spin orbit torque (SOT) layer, a MTJ and a top electrode. The SOT layer is disposed on the bottom electrode. The MTJ is disposed on the SOT layer. The top electrode is disposed on the MTJ. The top electrode includes a metal carbide layer.

According to another aspect of the present disclosure, a method for fabricating a MRAM device includes steps as follows. A bottom electrode is formed. A SOT layer is formed on the bottom electrode. A MTJ is formed on the SOT layer. A top electrode is formed on the MTJ. The top electrode includes a metal carbide layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7, FIG. 8 and FIG. 9 are schematic diagrams showing steps for fabricating a MRAM device according to an embodiment of the present disclosure.

FIG. 10 is a schematic cross-sectional view showing a MRAM device according to a comparative example of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

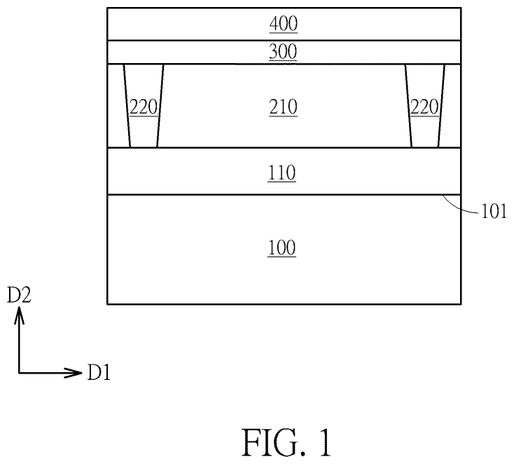

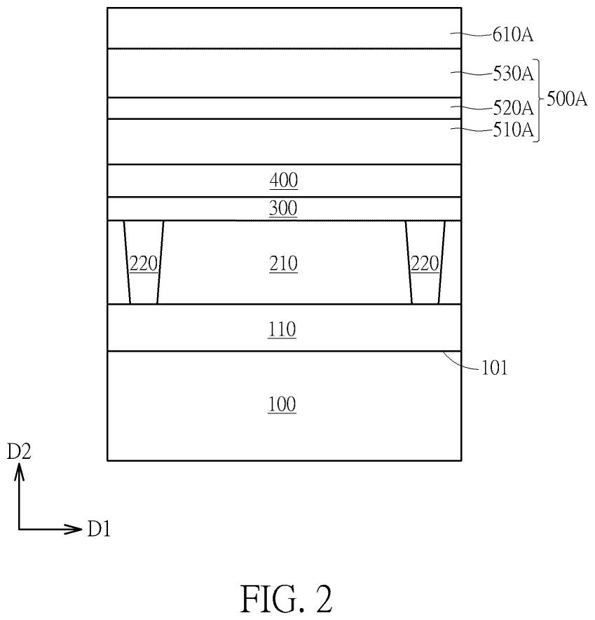

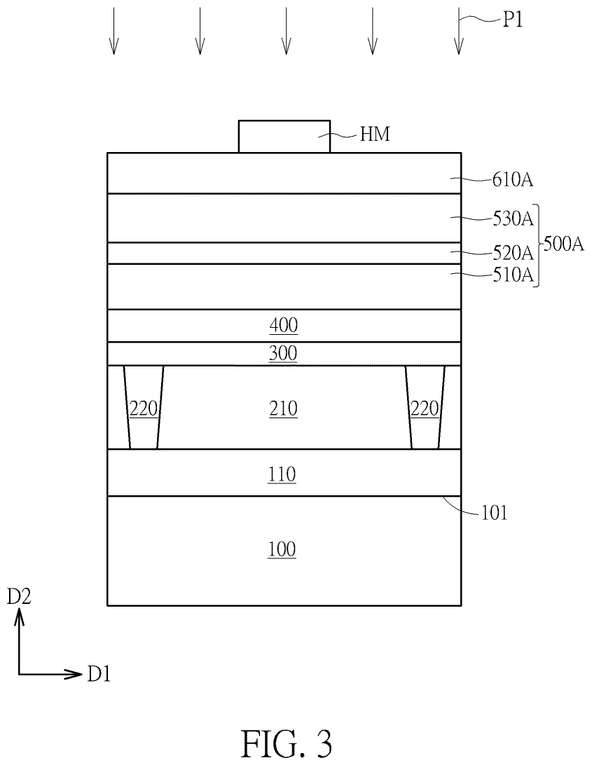

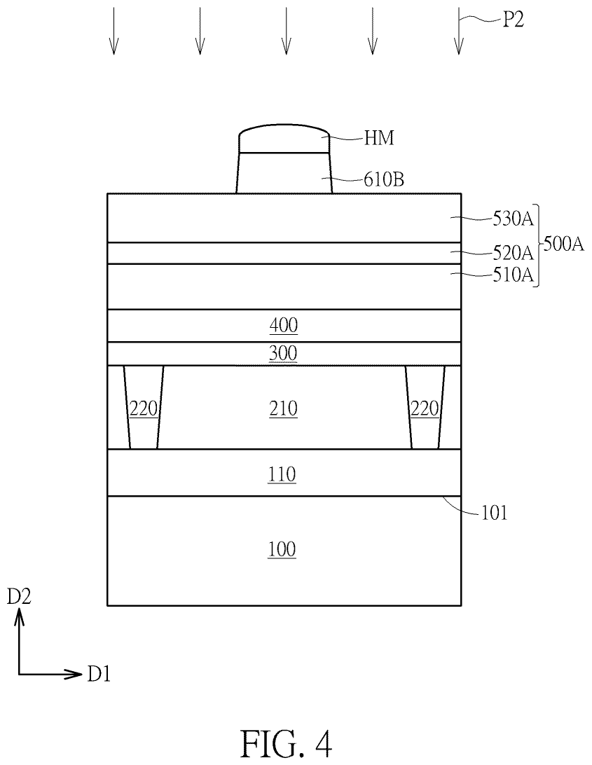

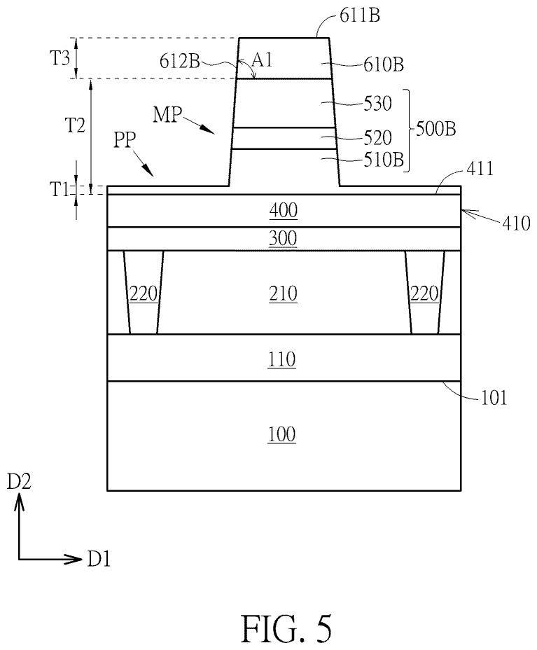

Please refer to FIG. 1 to FIG. 9, which are schematic diagrams showing steps for fabricating a MRAM device 10 according to an embodiment of the present disclosure. In FIG. 1, a substrate 100 is firstly provided. The substrate 100 may be a silicon substrate, an epitaxial silicon substrate, a silicon carbide substrate or a silicon on insulator (SOI) substrate. The substrate 100 may include a MRAM region (not labeled) and a logic region (not shown). FIG. 1 exemplarily shows the MRAM region of the substrate 100.

Active devices such as metal-oxide semiconductor (MOS) transistors (not shown), passive devices (not shown) and conductive layers (not shown) may be formed on the substrate 100.

Next, an interlayer dielectric (ILD) layer 110 is formed on the substrate 100 to cover the aforementioned active devices, passive devices and/or conductive layers. Specifically, the substrate 100 may include planar or non-planar (such as fin-shaped structure) MOS transistors. The MOS transistors may include transistor elements such as gate structures (such as metal gates), source/drain regions, spacers, epitaxial layers, and contact etch stop layer (CESL). The ILD layer 110 may be disposed on the substrate 100 to cover the MOS transistors, and a plurality of contact plugs (not shown) may be formed in the ILD layer 110 to electrically connect to the gate structures and/or the source/drain regions of the MOS transistors. Since the fabrications of the planar or non-planar MOS transistors and the ILD layer 110 are well known to those skilled in the art, the details thereof are omitted herein.

Next, an inter-metal dielectric layer 210 is formed on the ILD layer 110, and metal interconnections 220 are formed in the inter-metal dielectric layer 210. The metal interconnections 220 are for electrically connecting the aforementioned contact plugs in the ILD layer 110. The metal interconnections 220 may be embedded in the inter-metal dielectric layers 210 according to a single damascene process or a dual damascene process. Each of the metal interconnections 220 may be independently a single-layer structure or a multi-layer structure (not shown). For example, each of the metal interconnections 220 may include a low-resistance metal layer, and a material of the low-resistance metal layer may include, for example, tungsten (W), copper (Cu), aluminum (Al), titanium aluminum alloy (TiAl), cobalt tungsten phosphide (CoWP) or a combination thereof. The metal interconnection 220 may further include a barrier layer disposed between the low-resistance metal layer and the inter-metal dielectric layer 210. A material of the barrier layer may include titanium (Ti), titanium nitride (TiN), tantalum (Ta), tantalum nitride (TaN) or a combination thereof. A material of the inter-metal dielectric layer 210 may include tetraethoxysilane (TEOS) or silicon oxide, but not limited thereto. Since the single damascene process and the dual damascene process are well known to those skilled in the art, the details thereof are omitted herein.

Next, a bottom electrode 300 is formed on the inter-metal dielectric layer 210. A material of the bottom electrode 300 may (Ta), include titanium (Ti), titanium nitride (TiN), tantalum (tantalum nitride (TaN) or a combination thereof. Next, a SOT layer 400 is formed on the bottom electrode 300. A material of the SOT layer 400 may include tungsten (W), tantalum (Ta), platinum (Pt), hafnium (Hf) or a combination thereof.

Next, a MTJ 500 (see FIG. 7) is formed on the SOT layer 400, and a top electrode 600 (see FIG. 7) is formed on the MTJ 500, which may include steps as follows. First, as shown in FIG. 2, a MTJ material stack 500A is formed on the SOT layer 400, which includes sequentially forming a free material layer 510A, a barrier material layer 520A and a reference material layer (also called a pinned material layer) 530A on the SOT layer 400. The free material layer 510A may include a ferromagnetic material, such as iron, cobalt, nickel, or alloys thereof such as cobalt-iron-boron (CoFeB), but not limited thereto. The magnetized direction of the free material layer 510A may be altered freely depending on the influence of outside magnetic field. A material of the barrier material layer 520A may include an insulating material. For example, the insulating material may be an oxide, such as aluminum oxide or magnesium oxide (MgO), but not limited thereto. A material of the reference material layer 530A may include an antiferromagnetic (AFM) material, such as ferromanganese (FeMn), platinum manganese (PtMn), iridium manganese (IrMn) or nickel oxide (NiO), but not limited thereto. In some embodiments, the material of the reference material layer 530A may be identical to the material of the free material layer 510A.

Next, a metal carbide material layer 610A is formed on the MTJ material stack 500A. A material of the metal carbide material layer 610A may include tungsten carbide (WₓC, for example, x may be greater than or equal to 0.1 and less than or equal to 2).

Next, as shown in FIGS. 3 and 4, a portion of the metal carbide material layer 610A is removed to form a metal carbide layer 610B. Herein, a patterned mask HM is formed on the metal carbide material layer 610A, and an etching process P1 is performed to remove a portion of the metal carbide material layer 610A not covered by the patterned mask HM to form the metal carbide layer 610B. The material of the patterned mask HM may include an oxide, but not limited thereto. Furthermore, the patterned mask HM is also consumed by the etching process P1, so that the thickness of the patterned mask HM at the peripheral region is less than the thickness of the patterned mask HM at the central region. In other words, after the etching process P1 is performed, the top surface of the patterned mask HM changes from a flat surface to a convex surface.

Next, as shown in FIGS. 4 and 5, a portion of the MTJ material stack 500A is removed with the patterned mask HM and the metal carbide layer 610B as the mask to form a patterned MTJ material stack 500B. For example, an etching process P2 such as an ion beam etching process may be performed to remove a portion of the MTJ material stack 500A not covered by the metal carbide layer 610B.

It should be noted that in this step, by controlling the parameters of the etching process P2, such as the etching selectivity ratio of the patterned mask HM to the MTJ material stack 500A, the removing rate of the MTJ material stack 500A is greater than the removing rate of the patterned mask HM, so that the patterned mask HM may be completely removed at the end of the etching process P2. Preferably, at the end of the etching process P2, the patterned mask HM still has a remaining portion to protect the metal carbide layer 610B, and then the remaining portion of the patterned mask HM is removed. The portion of the reference material layer 530A not covered by the metal carbide layer 610B is completely removed to form the reference layer 530, the portion of the barrier material layer 520A not covered by the metal carbide layer 610B is completely removed to form the barrier layer 520, and the portion of the free material layer 510A not covered by the metal carbide layer 610B is partially removed to form a patterned free material layer 510B. Thereby, the patterned MTJ material stack 500B completely covers the SOT layer 400. In other words, during the entire etching process P2, the top surface 411 of the SOT layer 400 is not exposed, which can prevent the top surface 411 of the SOT layer 400 from being damaged to become uneven by the etching process P2. Accordingly, it is beneficial to improve the properties of MRAM device 10 formed later.

In addition, in the present disclosure, by using the patterned mask HM and the metal carbide layer 610B as the etching mask, the metal carbide layer 610B has excellent resistance for the etching process P2 even the patterned mask HM is completely consumed after the etching process P2. That is, after the etching process P2, the loss of the metal carbide layer 610B is very small. For example, there is almost no loss at the peripheral region of the metal carbide layer 610B, so that the thickness T3 of the metal carbide layer 610B is substantially fixed. For example, the thickness T3 of the metal carbide layer 610B at the peripheral region is equal to the thickness T3 of the metal carbide layer 610B at the central region. That is, the top surface 611B of the metal carbide layer 610B is a flat surface before and after the etching process P2. In addition, since the loss of the metal carbide layer 610B is very small, the side surface 612B of the metal carbide layer 610B is a vertical surface (i.e., the included angle A1 between the side surface 612B and the horizontal direction D1 is 90 degrees) or almost a vertical surface. According to an embodiment of the present disclosure, the included angle A1 between the side surface 612B and the horizontal direction D1 is greater than or equal to 85 degrees and less than or equal to 90 degrees. Alternatively, the included angle A1 is greater than or equal to 87 degrees and less than or equal to 89 degrees. Thereby, it is beneficial to improve the properties and yield of the MRAM device 10 formed later.

In FIG. 5, since a portion of the free material layer 510A not covered by the metal carbide layer 610B is partially reserved, the patterned MTJ material stack 500B includes different thicknesses. Specifically, the patterned MTJ material stack 500B includes a main portion MP and a peripheral portion PP. The peripheral portion PP is disposed adjacent to the main portion MP, and the thickness T1 of the peripheral portion PP is less than the thickness T2 of the main portion MP. The main portion MP is the portion of the patterned MTJ material stack 500B covered by the metal carbide layer 610B, and the peripheral portion PP is the portion of the patterned MTJ material stack 500B not covered by the metal carbide layer 610B. In addition, the peripheral portion PP and the metal carbide layer 610B does not overlap with each other in the vertical direction D2. Specifically, the thickness T1 is the thickness of the peripheral portion PP in the vertical direction D2, and the thickness T2 is the thickness of the main portion MP in the vertical direction D2. The vertical direction D2 may be perpendicular to the top surface 101 of the substrate 100.

Next, as shown in FIG. 6, an oxidation process P3 is performed, such as an O₂ plasma treatment process or an ion bombardment process, so that the material of the peripheral portion PP is completely converted into an oxide (not labeled) to form a patterned free material layer 510C to obtain the patterned MTJ material stack 500C, and a portion of the metal carbide layer 610B (the portion near the top end) is converted into a metal oxide layer 620. The portion of the metal carbide layer 610B that is not oxidized is the metal carbide layer 610. The thickness T4 of the metal carbide layer 610 is less than the thickness T3 of the metal carbide layer 610B. Since the oxidation process P3 mainly converts the portion of the metal carbide layer 610 near the top end into the metal oxide layer 620, the included angle A2 between the side surface 612 of the metal carbide layer 610 and the horizontal direction D1 is the same as the included angle A1.

Next, as shown in FIG. 7, the oxide of the peripheral portion PP is removed to expose the portion 410 of the SOT layer 400 located below the peripheral portion PP, so as to complete the fabrication of the MTJ 500. For example, an acidic solution may be used to react with the oxide of the peripheral portion PP to remove the oxide. According to an embodiment of the present disclosure, the aforementioned acidic solution may be a dilute hydrofluoric acid, but not limited thereto. The type of acidic solution may be adjusted according to the material of the SOT layer 400 and the type of the oxide, so that the oxide of the peripheral portion PP can be removed completely, while the metal oxide layer 620 is not removed or is partially removed. In FIG. 7, the MTJ 500 includes a free layer 510, a barrier layer 520 and a reference layer 530 from bottom to top.

Next, a nitridation process P4 is performed to convert the metal oxide layer 620 into a metal nitride layer 630. For example, in the nitridation process P4, a mixed gas of hydrogen and nitrogen (H₂/N₂) may be introduced to replace the oxygen atoms of the metal oxide layer 620 with nitrogen atoms to convert the metal oxide layer 620 into the metal nitride layer 630. The metal oxide layer 620 and the metal nitride layer 630 may together form the top electrode 600.

In other embodiments, the oxidation process P3 can be omitted to directly perform the nitridation process P4, so that the material of the peripheral portion PP is completely converted into a nitride, and a portion of the metal carbide layer 610B (the portion near the top end) is converted into the metal nitride layer 630, then an etching solution is used to completely remove the nitride of the peripheral portion PP to expose the portion 410 of the SOT layer 400 located below the peripheral portion PP, and the etching solution does not remove the metal nitride layer 630.

Next, as shown in FIG. 8, a dielectric cap layer 700 is formed to cover the top electrode 600, the MTJ 500 and the SOT layer 400. The material of the dielectric cap layer 700 may include, but is not limited to, nitrogen doped carbide (NDC), silicon nitride or silicon carbon nitride (SiCN), but not limited thereto. In the embodiment, the material of the dielectric cap layer 700 includes silicon nitride.

Next, as shown in FIG. 9, a wire 820 is formed to electrically connect with the top electrode 600. For example, an inter-metal dielectric layer 810 may be formed on the dielectric cap layer 700, and then a hole 830 may be formed in the inter-metal dielectric layer 810. Afterward, the wire 820 may be formed in the hole 830. The wire 820 may be a single-layer structure or a multi-layer structure (not shown). For example, the wire 820 may include a low-resistance metal layer, and a material of the low-resistance metal layer may include, for example, tungsten (W), copper (Cu), aluminum (Al), titanium aluminum alloy (TiAl), cobalt tungsten phosphide (CoWP) or a combination thereof. The wire 820 may further include a barrier layer disposed between the low-resistance metal layer and the inter-metal dielectric layer 810. A material of the barrier layer may include titanium (Ti), titanium nitride (TiN), tantalum (Ta), tantalum nitride (TaN) or a combination thereof. A material of the inter-metal dielectric layer 810 may include tetraethoxysilane (TEOS) or silicon oxide, but not limited thereto. Thereby, the fabrication of the MRAM device 10 is completed.

The aforementioned film layers, such as the ILD layer 110, the inter-metal dielectric layer 210, the bottom electrode 300, the SOT layer 400, and the MTJ material stack 500A, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

FIG. 9 shows the MRAM device 10 according to one embodiment of the present disclosure. The MRAM device 10 includes the bottom electrode 300, the SOT layer 400, the MTJ 500 and the top electrode 600. The SOT layer 400 is disposed on the bottom electrode 300. The MTJ 500 is disposed on the SOT layer 400. The top electrode 600 is disposed on the MTJ 500. The top electrode 600 includes the metal carbide layer 610. A material of the metal carbide layer 610 may include tungsten carbide (WₓC, for example, x may be greater than or equal to 0.1 and less than or equal to 2).

In FIG. 9, the SOT layer 400 includes a portion 410 exposed from the MTJ 500 (i.e., the portion 410 is not covered by the MTJ 500). The top surface 411 of the portion 410 is aligned with the bottom surface 503 of the MTJ 500.

The top electrode 600 may optionally further include a metal nitride layer 630 disposed on the metal carbide layer 610. According to an embodiment of the present disclosure, the metal nitride layer 630 is formed by firstly oxidizing a portion of the metal carbide layer 610B to form the metal oxide layer 620 and then nitridizing the metal oxide layer 620. Therefore, the metal carbide layer 610 and the metal nitride layer 630 include a same metal composition. For example, when the material of the metal carbide layer 610 includes tungsten carbide, the material of the metal nitride layer 630 includes tungsten nitride.

According to an embodiment of the present disclosure, the thickness T4 of the metal carbide layer 610 may range from 200 angstroms (Å) to 400 Å. The ratio of the thickness T4 of the metal carbide layer 610 to the thickness T5 of the metal nitride layer 630 may range from 10 to 40. The thickness T5 of the metal nitride layer 630 may range from 10 Å to 20 Å.

As mentioned above, the metal carbide layer 610B has excellent resistance to the etching process P2. After the etching process P2, the thickness T3 of the metal carbide layer 610B is substantially fixed, the top surface 611B of the metal carbide layer 610B is a flat surface, and the side surface 612B is a vertical surface or is almost a vertical surface. Therefore, the thickness T6 of the top electrode 600 is also substantially fixed, the top surface 601 of the top electrode 600 is also a flat surface, and the side surface 602 of the top electrode 600 is also a vertical surface or almost a vertical surface.

Specifically, in the cross-sectional view of the MRAM device 10, an included angle A3 is between the side surface 602 of the top electrode 600 and the bottom surface 603 of the top electrode 600, and the included angle A3 is equal to the aforementioned included angle A2. That is, the included angle A3 may be greater than or equal to 85 degrees and less than or equal to 90 degrees. Alternatively, the included angle A3 may be greater than or equal to 87 degrees and less than or equal to 89 degrees. In FIG. 9, in the cross-sectional view of the MRAM device 10, the top electrode 600 may include a rectangular shape or a trapezoidal shape. Specifically, when the included angle A3 is greater than or equal to 85 degrees and less than 90 degrees, the top electrode 600 may include a trapezoidal shape. When the included angle A3 is equal to 90 degrees, the top electrode 600 may include a rectangular shape.

In FIG. 9, the bottom surface 823 of the wire 820 corresponding to the top surface 601 of the top electrode 600 is also a flat surface. Specifically, in the present disclosure, with the thickness T6 of the top electrode 600 being substantially fixed, it is favorable for the hole 830 to stop on the top surface 601 of the top electrode 600 when forming the hole 830 for disposing the wire 820, so that the wire 820 are located on the top surface 601 of the top electrode 600. Therefore, it can prevent the wire 820 from contacting the reference layer 530 of the MTJ 500 along the side surface 602 of the top electrode 600 to cause a short circuit.

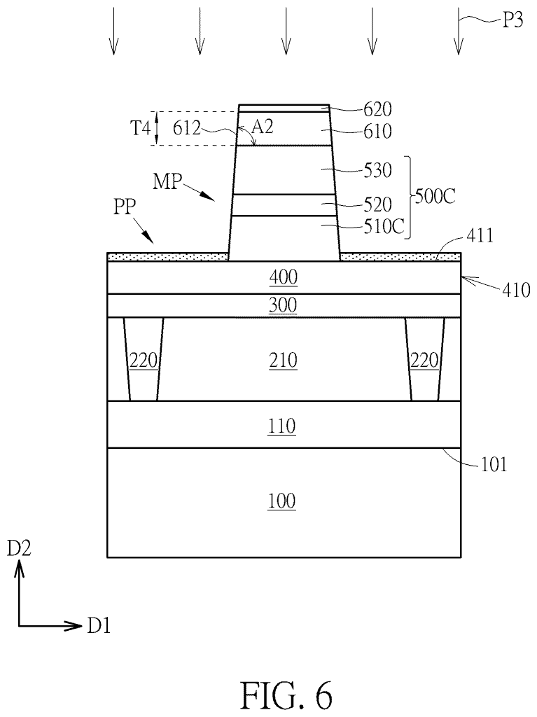

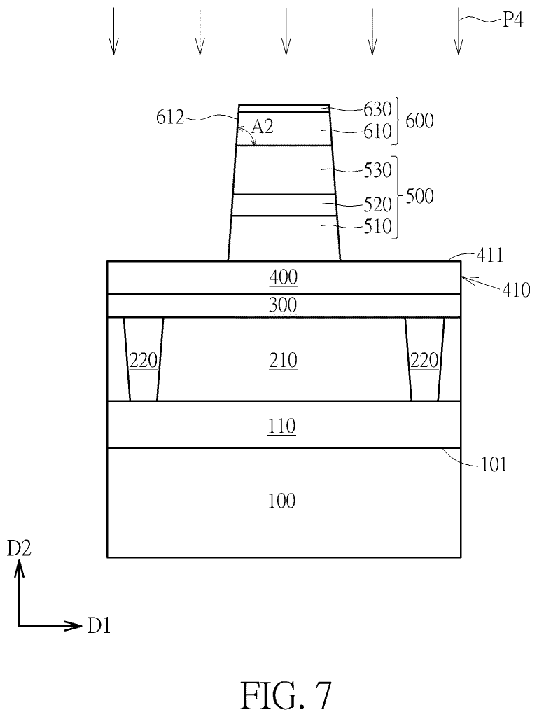

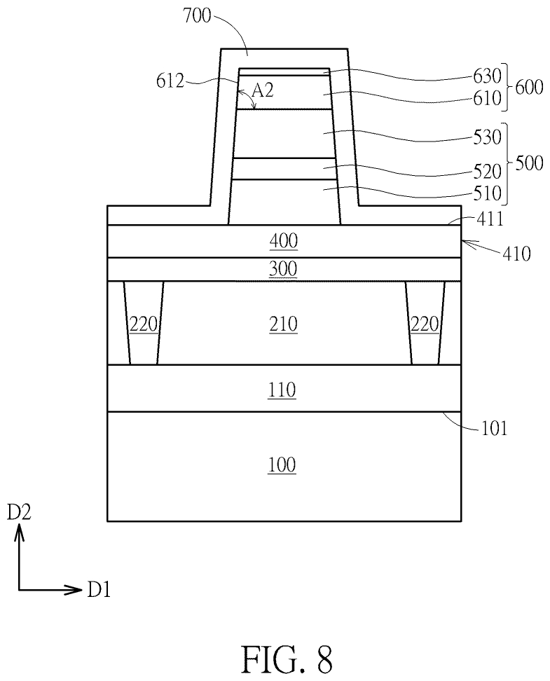

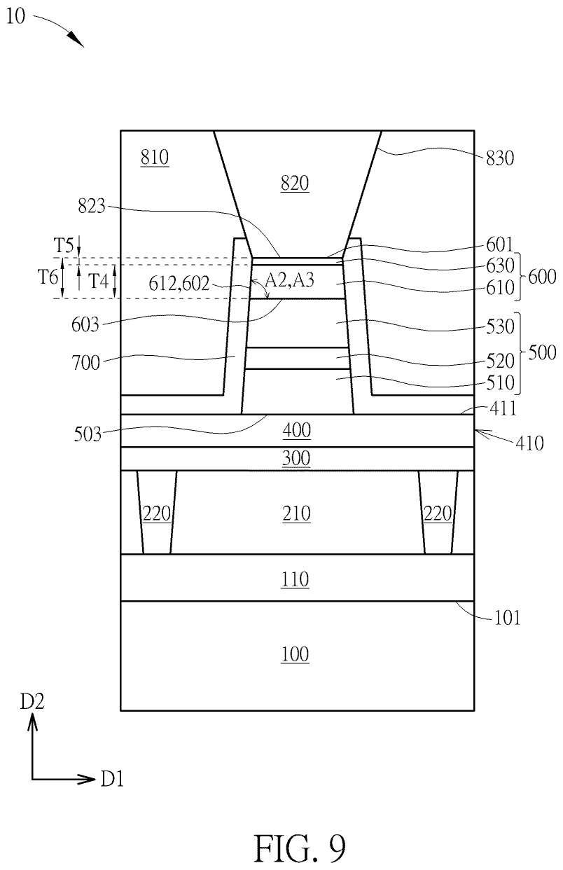

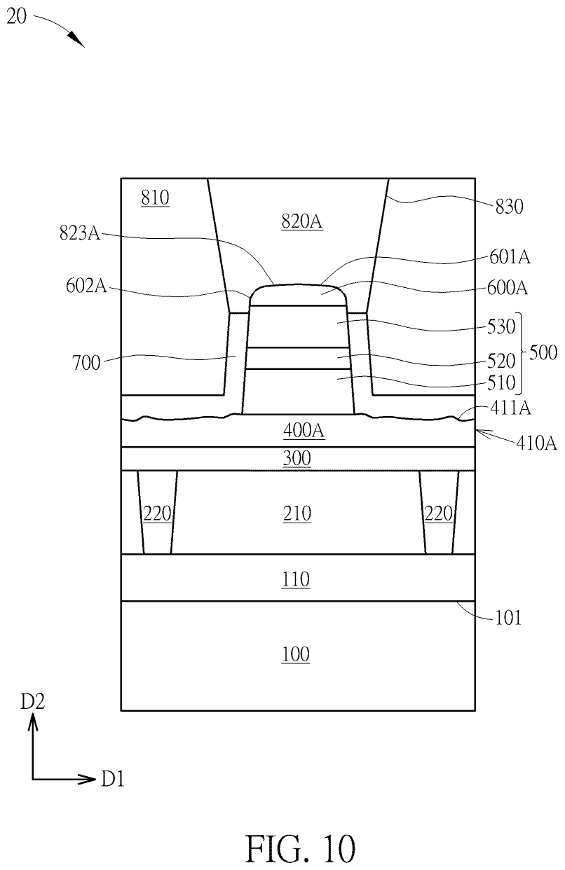

Please refer to FIG. 10, which is a schematic cross-sectional view showing a MRAM device 20 according to a comparative example of the present disclosure. The main difference between the MRAM device 20 and the MRAM device 10 is that the material of the top electrode 600A is different from that of top electrode 600, and the top surface 411A of the portion 410A of the SOT layer 400A exposed from the MTJ 500 is uneven. Specifically, the material of the top electrode 600A is exemplary as titanium nitride. When fabricating the MRAM device 20, in the step corresponding to FIG. 4, the portion of the free material layer 510A not covered by the metal carbide layer 610B is also completely removed. Therefore, the top surface 411A of the SOT layer 400A is exposed and damaged by the etching process P2 to become uneven, and the properties of the MRAM device 20 are affected.

In addition, the resistance of titanium nitride to the etching process P2 is poorer than that of the metal carbide layer 610B. Therefore, after the etching process P2, the peripheral region of the top electrode 600A is consumed. The thickness of the peripheral region of the top electrode 600A becomes thinner, and the top surface 601A of the top electrode 600A becomes a convex surface. In addition, an inclined degree of the side surface 602A of the top electrode 600A is larger. The steps corresponding to FIGS. 6 and 7 are omitted when fabricating the MRAM device 20. When forming the hole 830 for disposing the wire 820A, it is unfavorable for the hole 830 to stop on the top surface 601A of the top electrode 600A due to the peripheral region of the top electrode 600A having a thinner thickness, so that a portion of the reference layer 530 is exposed, and the wire 820A has a concave bottom surface 823A. The wire 820A contacts the reference layer 530 of the MTJ 500 to cause a short circuit. As a result, the yield of the MRAM device 20 is reduced.

Compared with the prior art, the MRAM device according to the present disclosure adopts the SOT technology to switch the magnetic moment, which affects the magnetic moment of the free layer by spin current. Therefore, it is beneficial to improve the write speed of the MRAM device. Moreover, in the MRAM device of the present disclosure, the material of the top electrode includes a metal carbide layer. When a portion of the MTJ material stack is removed by an etching process to form the MTJ, the metal carbide layer is more resistant to the etching process. Therefore, the peripheral region of the top electrode is hard to consume by the etching process, and the properties and the yield of the MRAM device can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A magnetoresistive random access memory (MRAM) device, comprising:
a bottom electrode;
a spin orbit torque (SOT) layer disposed on the bottom electrode;
a magnetic tunneling junction (MTJ) disposed on the SOT layer; and
a top electrode disposed on the MTJ, wherein the top electrode comprises a metal carbide layer.

2. The MRAM device of claim 1, wherein a material of the metal carbide layer comprises tungsten carbide.

3. The MRAM device of claim 1, wherein a thickness of the metal carbide layer ranges from 200 Å to 400 Å.

4. The MRAM device of claim 1, wherein the top electrode further comprises a metal nitride layer disposed on the metal carbide layer, and the metal carbide layer and the metal nitride layer comprise a same metal composition.

5. The MRAM device of claim 4, wherein a ratio of a thickness of the metal carbide layer to a thickness of the metal nitride layer ranges from 10 to 40.

6. The MRAM device of claim 5, wherein a thickness of the metal nitride layer ranges from 10 Å to 20 Å.

7. The MRAM device of claim 1, wherein a top surface of the top electrode is a flat surface.

8. The MRAM device of claim 1, wherein in a cross-sectional view of the MRAM device, an included angle is between a side surface of the top electrode and a bottom surface of the top electrode, and the included angle is greater than or equal to 85 degrees and less than or equal to 90 degrees.

9. The MRAM device of claim 1, wherein in a cross-sectional view of the MRAM device, the top electrode comprises a rectangular shape or trapezoidal shape.

10. The MRAM device of claim 1, wherein a portion of the SOT layer is exposed from the MTJ, and a top surface of the portion of the SOT layer is aligned with a bottom surface of the MTJ.

11. A method for fabricating a MRAM device, comprising:
forming a bottom electrode;
forming a SOT layer on the bottom electrode;
forming a MTJ on the SOT layer; and
forming a top electrode on the MTJ, wherein the top electrode comprises a metal carbide layer.

12. The method of claim 11, further comprising:
forming a MTJ material stack on the SOT layer;
forming a metal carbide material layer on the MTJ material stack;
removing a portion of the metal carbide material layer to form the metal carbide layer; and
removing a portion of the MTJ material stack with the metal carbide layer as a mask to form a patterned MTJ material stack.

13. The method of claim 12, wherein the portion of the MTJ material stack is removed by an ion beam etching process.

14. The method of claim 12, wherein the patterned MTJ material stack completely covers the SOT layer.

15. The method of claim 14, wherein the patterned MTJ material stack comprises a main portion and a peripheral portion disposed adjacent to the main portion, and a thickness of the peripheral portion is less than a thickness of the main portion.

16. The method of claim 15, further comprising:
performing an oxidation process to completely convert a material of the peripheral portion into an oxide.

17. The method of claim 16, further comprising:
removing the oxide to expose a portion of the SOT layer located below the peripheral portion.

18. The method of claim 16, wherein performing the oxidation process further comprises to convert a portion of the metal carbide layer into a metal oxide layer.

19. The method of claim 18, further comprising:
performing a nitridation process to convert the metal oxide layer into a metal nitride layer.

20. The method of claim 11, further comprising:
forming a dielectric cap layer to cover the top electrode, the MTJ and the SOT layer; and
forming a wire to electrically connect with the top electrode, wherein a bottom surface of the wire is a flat surface.
